(19) United States
(12) Patent Application Publication
(10) Pub. No.: US 2014/0141191 A1
(43) Pub. Date: May 22, 2014

(54) Hydrophobic and Oleophobic Encapsulation Material with Alternating Layers

(71) Applicant: Veeco ALD Inc., Fremont, CA (US)

(72) Inventor: Sang In Lee, Sunnyvale, CA (US)

(73) Assignee: Veeco ALD Inc., Fremont, CA (US)

(21) Appl. No.: 14/052,106

(22) Filed: Oct. 11, 2013

Related U.S. Application Data
(60) Provisional application No. 61/728,648, filed on Nov. 20, 2012.

(51) Int. Cl. C09D 5/00; H01L 51/52; H01L 31/048; H01G 9/004

(52) U.S. Cl. CPC C09D 5/00; H01G 9/004; H01L 51/5256; H01L 31/0481
USPC 428/76; 427/419.1; 427/535; 427/407.1; 428/696; 428/333; 428/522

(57) ABSTRACT

An encapsulation material is described that prevents moisture or oily substances from penetrating into a protected region or device. The encapsulation material includes alternating layers of a hydrophobic and oleophobic first layer and a hydrophilic second layer. The second hydrophilic layer traps water molecules, preventing them from migrating. By alternating hydrophobic/oleophobic layers with hydrophilic layers (including hydrophobic layers having a thickness of approximately that of a water molecule or a hydroxyl ion), the encapsulation material forms multiple, finite energetic wells at the hydrophilic layers. These potential wells confine water molecules, oxygen molecules, and hydroxyl ions preventing migration of through the encapsulation material.

### CROSS REFERENCE TO RELATED APPLICATIONS

This application claims priority to and the benefit under 35 U.S.C. §119 (e) to U.S. Provisional Application No. 61/728,648, filed Nov. 20, 2012, which is incorporated by reference in its entirety.

### BACKGROUND

1. Field of Art

The disclosure relates generally to encapsulation materials. In particular, the present disclosure relates to a hydrophobic and oleophobic encapsulation material with alternating layers.

2. Description of the Related Art

Various products benefit from protection or encapsulation to prevent contamination from, for example, moisture or oily substances. Example products benefiting from encapsulation include, among others, electronic devices (e.g., components for display devices or solar cells), and food or other perishable goods.

By forming an encapsulation material on a product itself, or using the encapsulation material as an element of the packaging for the product, moisture and/or oily substances are prevented from contacting the products that otherwise are likely to be damaged or deteriorate when exposed to a contaminant. For example, an encapsulation material can be used to protect a product by attaching it to a substrate (e.g., touchscreen glass, plastic package, or integrated circuit) so that it functions as a protective layer. Alternatively, the encapsulation material may be used in conjunction with a more durable material placed on the encapsulation material.

Perfluoropolymers may be used as a hydrophobic encapsulation material since perfluoropolymers are chemically stable, chemical and weather resistant, have oil and water-repellency, low surface tension, low refractive index, low friction coefficient and reduced adhesion to surfaces. However, perfluoropolymers do not have good adhesion characteristics. Therefore, when a perfluoropolymer is used as coating material, it tends to delaminate from the substrate or other element of the product or packaging that the perfluoropolymer is attached to.

### SUMMARY

Embodiments relate to a method for fabricating an encapsulation material including providing a bottom layer of an inorganic material, forming a hydrophobic first layer of an inorganic compound of at least one metal or at least one semi-metal, and oxygen, and fluorine, the hydrophobic first layer disposed on the bottom layer, and forming a first alternating-layer stack by forming an inorganic hydrophilic second layer on the first layer, the second layer providing an energetic well for trapping water molecules and hydroxyl ions.

In one embodiment, the bottom layer is provided by adsorbing a metal-organic precursor layer on a substrate using atomic layer deposition and exposing the metal-organic precursor layer to a radical species from a plasma, the plasma converting a surface portion of the metal-organic precursor layer to the inorganic compound of the first layer.

In one embodiment, the bottom layer is provided further by exposing the inorganic material of the bottom layer to a fluorine containing plasma to form an inorganic layer containing elements of the inorganic material and fluorine as the first layer.

In one embodiment, the bottom layer is provided further by exposing the inorganic material of the bottom layer to a fluorine and silane containing plasma to form an inorganic layer containing elements of the inorganic material, silicon, carbon, and fluorine as the first layer.

In one embodiment, the bottom layer is provided further by exposing the inorganic material of the bottom layer to a fluorine containing plasma with a titanium containing precursor to form an inorganic layer containing elements of the inorganic material, and titanium, carbon, and fluorine as the first layer.

In one embodiment, the hydrophobic first layer is provided by depositing a polymer, a plasma polymer (i.e., a polymer polymerized using a plasma), or a polymer of aluminum, oxygen, carbon, and fluorine on the bottom layer.

In one embodiment, the hydrophobic first layer is from one angstrom to 100 angstroms thick.

In one embodiment, fabricating the encapsulation material includes providing the hydrophobic first layer by exposing the bottom layer to tridecafluoro-1,1,2,2-tetrahydrooctylmethylbis(dimethylamino)silane and causing the deposited tridecafluoro-1,1,2,2-tetrahydrooctylmethylbis(dimethylamino)silane to react with trimethylaluminum in the bottom layer to form an Al—Si—O—C—F polymer as the first layer on the bottom layer.

In one embodiment, the inorganic hydrophilic second layer is provided by exposing the first layer to a metal-organic precursor, molecules of which are adsorbed on the first layer and exposing the adsorbed metal-organic molecules to radicals of a plasma to convert the adsorbed metal-organic to an inorganic layer.

In one embodiment, at least one additional alternating-layer stack is formed on the first alternating-layer stack.

In one embodiment, the bottom layer is provided by exposing a substrate to a metal-organic precursor, purging physisorbed metal-organic precursor from the substrate by injecting an inert gas onto the substrate, exposing the metal-organic molecules remaining on the substrate after the purging to radicals generated from a plasma, and providing an organic precursor to the metal-organic molecules remaining on the substrate and exposed to the radicals.

In one embodiment, the inorganic hydrophilic second layer is from one angstrom to five angstroms thick.

Other embodiments relate to an encapsulation material including a bottom layer of an inorganic material, and a first alternating-layer stack. The first alternating-layer stack includes a hydrophobic first layer and an inorganic hydrophilic second layer disposed on the first layer. The second layer provides an energetic well for trapping water molecules and hydroxyl ions.

In one embodiment, the bottom layer is one of Al₂O₃, ZrO₂, HfO₂, SiO₂, TiO₂, and combinations thereof.

In one embodiment, the hydrophobic first layer is a polymer.

In one embodiment, the second layer has a thickness substantially equal to a molecular diameter of a water molecule.

In one embodiment, the hydrophobic first layer is an organic aluminum-oxygen-carbon-fluorine compound.

In one embodiment, the hydrophobic first layer is an inorganic aluminum-oxygen-fluorine compound.

In one embodiment, the hydrophobic first layer is fabricated by exposing the bottom layer to a fluorine-containing plasma to convert a surface of the bottom layer to the inorganic aluminum-oxygen-fluorine compound of the hydrophobic first layer.

In one embodiment, the hydrophobic first layer is a polymer.

In one embodiment, the first layer is formed by exposing a substrate to glycidylmethacrylate to deposit a layer of glycidylmethacrylate and exposing the deposited layer of glycidylmethacrylate to an N₂O plasma to convert the deposited layer to poly(glycidylmethacrylate).

In one embodiment, the encapsulation material includes at least one additional alternating-layer stack on the first alternating-layer stack.

Other embodiments relate to a device including at least one active layer and an encapsulation layer protecting the at least one active layer from contamination. The encapsulation layer may include an inorganic material, and a first alternating-layer stack. The first alternating-layer stack includes a hydrophobic first layer compound disposed on the bottom layer and an inorganic hydrophilic second layer disposed on the hydrophobic first layer. The second layer provides an energetic well for trapping water molecules and hydroxyl ions.

Still other embodiments relate to a device including at least one active layer, an encapsulation layer protecting the at least one active layer from contamination. The encapsulation layer includes a bottom layer of an inorganic material, and a first alternating-layer stack. The first alternating-layer stack includes a hydrophobic first layer disposed on the bottom layer, an inorganic hydrophilic second layer disposed on the hydrophobic first layer. The second layer provides an energetic well for trapping water molecules and hydroxyl ions, and at least one additional alternating-layer stack on the first alternating-layer stack.

### BRIEF DESCRIPTION OF DRAWINGS

FIG. 1 is a cross sectional diagram of a linear deposition device, according to one embodiment.

FIG. 2 is a perspective view of a linear deposition device, according to one embodiment.

FIG. 3 is a perspective view of a rotating deposition device, according to one embodiment.

FIG. 4 is a perspective view of reactors in a deposition device, according to one embodiment.

FIG. 5 is a cross sectional diagram of an encapsulation material, according to one embodiment.

FIG. 6 is a flowchart illustrating a process of forming an encapsulation material, according to one embodiment.

FIG. 7 is a block diagram of a display device including an organic light emitting diode protected from contamination by an encapsulation material, according to one embodiment.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

In the drawings, like reference numerals in the drawings denote like elements. The shape, size and regions, and the like, of the drawing may be exaggerated for clarity.

Embodiments relate to forming an encapsulation material that prevents moisture or oily substances from penetrating into a protected region or device. The encapsulation material of the present disclosure includes alternating layers of a first that is hydrophobic and oleophobic and a second layer that is hydrophilic and traps any water molecules to prevent water molecules from diffusing into the first layers surrounding the second layer. By alternating the first layer (e.g., a hydrophobic layer having a thickness of approximately that of a water molecule or a hydroxyl ion) with second layer, the encapsulation material forms multiple, finite potential wells at the first layer. These potential wells confine water molecules and oxygen molecules, preventing or reducing migration of water and/or oxygen through the encapsulation material.

In one or more embodiments, the first and second layers are formed from the same material. In some examples, the first layer is formed by exposing part the same material to fluorine plasma. The remaining material not exposed to the fluorine plasma becomes the second layer.

In other embodiments, the second layer may be deposited on the first layer using a separate chemical vapor deposition (CVD), atomic layer deposition (ALD) or molecular layer deposition (MLD) process. For example, trimethylaluminium (TMA) may be used as source precursor followed by N₂O plasma as reactant precursor to deposit aluminum oxide as the second layer.

### Example Deposition Device

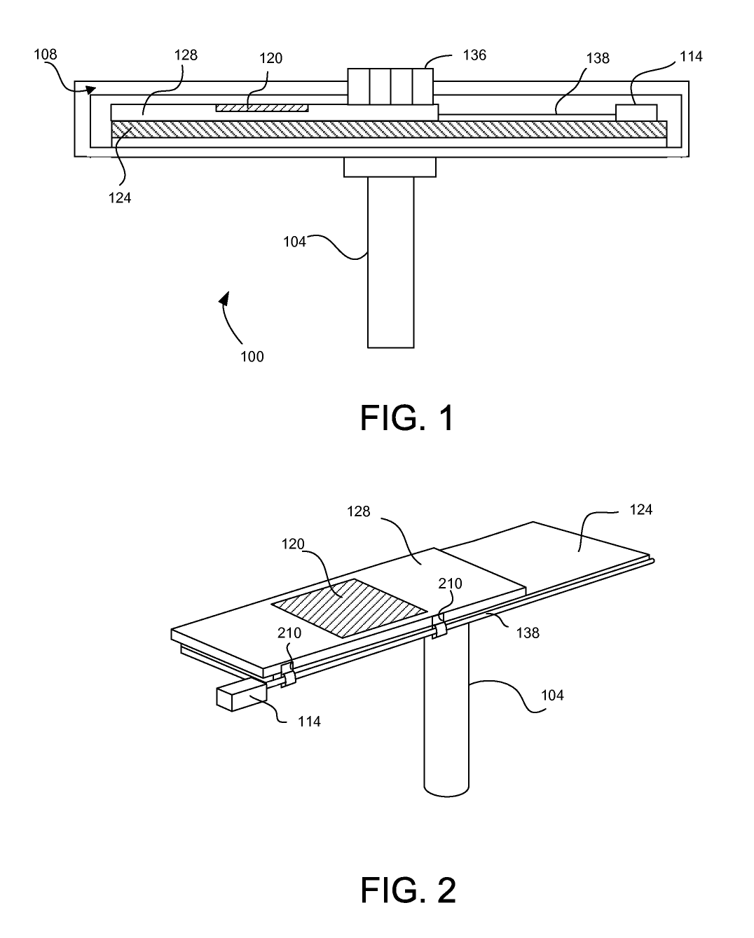

FIG. 1 is a cross sectional diagram of a linear deposition device 100, according to one embodiment. FIG. 2 is a perspective view of the linear deposition device 100 (without chamber walls to facilitate explanation), according to one embodiment. The linear deposition device 100 may include, among other components, a support pillar 104, a process chamber 108 and one or more reactors 136. The reactors 136 may include one or more of injectors and radical reactors for performing MLD, ALD and/or CVD. The injectors inject source precursors, reactant precursors, purge gases or combinations thereof onto a substrate 120. The gap between the injector and the substrate 120 may be 0.5 mm to 1.5 mm.

The process chamber 108 is enclosed by walls and may be maintained in a vacuum state to prevent contaminants from affecting the deposition process by providing an inert environment in which to perform the deposition process. The process chamber 108 contains a susceptor 128 which receives a substrate 120. The susceptor 128 is placed on a support plate 124 for a sliding movement. The support plate 124 may include a temperature controller (e.g., a heater or a cooler) to control the temperature of the substrate 120. Conventionally, the substrate 120 is heated to a temperature of over 250° C., sometimes over 500° C. depending on the precursor being used and the material being deposited on the substrate 120. However, embodiments enable the temperature of the substrate 120 to be maintained at a lower temperature by heating the precursor instead of the substrate 120.

The linear deposition device 100 may also include lift pins (not shown) that facilitate loading of the substrate 120 onto the susceptor 128 or dismounting of the substrate 120 from the susceptor 128.

FIG. 2 is a perspective view of the linear deposition device 100 (without chamber walls to facilitate explanation), an embodiment of which was described above in the context of FIG. 1. In one embodiment, the susceptor 128 is secured to brackets 210 that move across an extended bar 138 with screws formed thereon. The brackets 210 have corresponding screws formed in their holes receiving the extended bar 138. The extended bar 138 is secured to a spindle of a motor 114, and hence, the extended bar 138 rotates as the spindle of the motor 114 rotates. The rotation of the extended bar 138 causes the brackets 210 (and therefore the susceptor 128) to make a linear movement on the support plate 124. By controlling the speed and rotation direction of the motor 114, the speed and the direction of the linear movement of the susceptor 128 can be controlled. The use of a motor 114 and the extended bar 138 is merely an example of a mechanism for moving the susceptor 128. Various other ways of moving the susceptor 128 (e.g., use of gears and pinion or a linear motor at the bottom, top or side of the susceptor 128). Moreover, instead of moving the susceptor 128, the susceptor 128 may remain stationary and the reactors 136 may be moved.

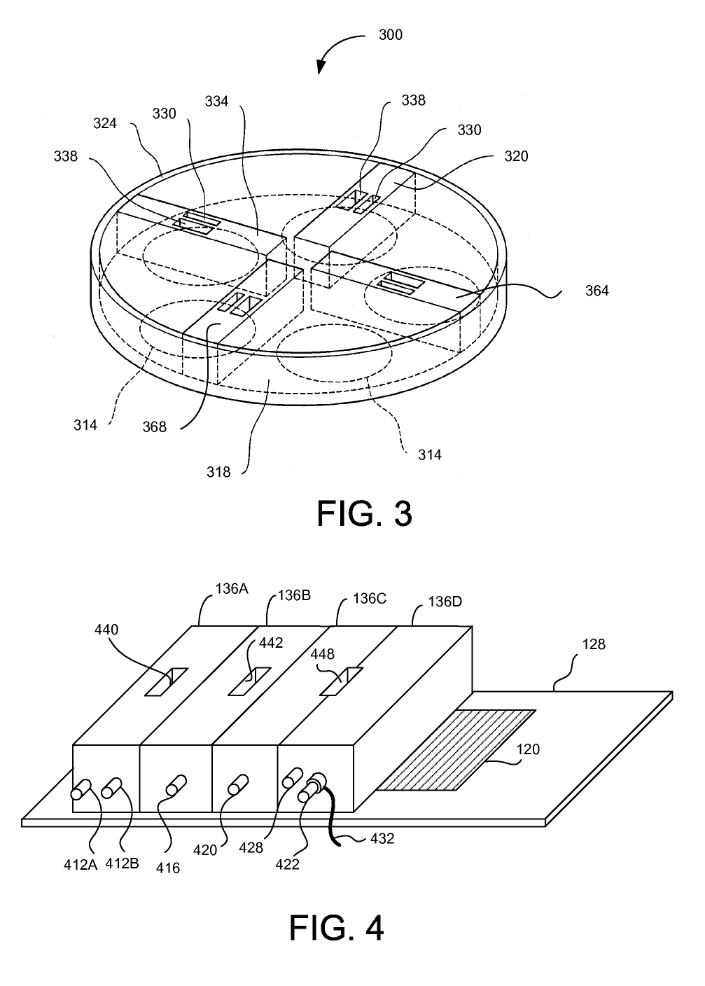

FIG. 3 is a perspective view of a rotating deposition device 300, according to one embodiment. Instead of using the linear deposition device 100 of FIG. 1, the rotating deposition device 300 may be used to perform the deposition process according to another embodiment. The rotating deposition device 300 may include, among other components, reactors 320, 334, 364, 368, a susceptor 318, and a container 324 enclosing these components. A reactor (e.g., 320) of the rotating deposition device 300 corresponds to a reactor 136 of the linear deposition device 100, as described above with reference to FIG. 1. The susceptor 318 secures the substrates 314 in place. The reactors 320, 334, 364, 368 may be placed with a gap of 0.5 mm to 1.5 mm from the substrates 314 and the susceptor 318. Either the susceptor 318 or the reactors 320, 334, 364, 368 rotate to subject the substrates 314 to different processes.

One or more of the reactors 320, 334, 364, 368 are connected to gas pipes (not shown) to provide source precursor, reactor precursor, purge gas and/or other materials. The materials provided by the gas pipes may be (i) injected onto the substrate 314 directly by the reactors 320, 334, 364, 368, (ii) after mixing in a chamber inside the reactors 320, 334, 364, 368, or (iii) after conversion into radicals by plasma generated within the reactors 320, 334, 364, 368. After the materials are injected onto the substrate 314, the redundant materials may be exhausted through outlets 330, 338. The interior of the rotating deposition device 300 may also be maintained in a vacuum state.

The rotating deposition device 300 may also be equipped with one or more heaters to increase the temperature of the substrate 314.

Although following example embodiments are described primarily with reference to the reactors 136 in the linear deposition device 100, the same principle and operation can be applied to the rotating deposition device 300 or other types of deposition device.

FIG. 4 is a perspective view of reactors 136A through 136D (collectively referred to as the “reactors 136”) in the deposition device 100 of FIG. 1, according to one embodiment. The reactors 136A through 136D are placed in tandem adjacent to each other. In other embodiments, the reactors 136A through 136D may be placed with a distance from each other. As the susceptor 128 mounting the substrate 120 moves from the left to the right or from the right to the left, the substrate 120 is sequentially injected with materials or radicals by the reactors 136A through 136D to form a deposition layer on the substrate 120. Instead of moving the substrate 120, the reactors 136A through 136D may move from the right to the left while injecting the source precursor materials or the radicals on the substrate 120.

In one or more embodiments, the reactors 136A, 136B, 136C are gas injectors that inject precursor material, purge gas or a combination thereof onto the substrate 120. Each of the reactors 136A, 136B, 136C is connected to pipes 412A, 412B, 416, 420 to receive precursors, purge gas or a combination thereof from one or more sources. Valves and other pipes may be installed between the pipes 412A, 412B, 416, 420 and the sources to control the gas and the amount thereof provided to the gas injectors 136A, 136B, 136C. Excess precursor and purge gas molecules are exhausted via exhaust portions 440, 442, 448.

The reactor 136D may be a radical reactor that generates radicals of gas or a gas mixture received from one or more sources. The radicals of gas or gas mixture may function as purge gas, reactant precursor, surface treating agent, or a combination thereof on the substrate 120. The gas or gas mixtures are injected into the reactor 136D via pipe 428, and are converted into radicals within the reactor 136D by applying voltage across electrodes (e.g., electrode 422 and body of the reactor 136C) and generating plasma within a plasma chamber. The electrode 422 is connected via a line 432 to a supply voltage source and the body of the reactor 136, which forms a coaxial capacitive-type plasma reactor, is grounded or connected to the supply voltage source via a conductive line (not shown). The generated radicals are injected onto the substrate 120 with traveling distances not longer than 50 mm, and remaining radicals and/or gas reverted to an inactive state from the radicals are discharged from the reactor 136D via the exhaust portion 448. By exposing the substrate 120 to the radicals, the surface of the substrate maintained reactive until the next precursor is injected onto the surface of the substrate.

In one example of the foregoing process, an oxygen-containing gas or gas mixture is used to generate oxygen radicals (O*), hydrogen radicals (H*), and/or hydroxyl radicals ((OH)*) by exposing the input gas to a high voltage source, thereby forming a plasma. In the example of an oxygen plasma, the lifetime of the oxygen radicals is approximately in the range of 1 milliseconds to 10 milliseconds (compared to approximately 200 microseconds for a hydroxyl radical) at a pressure of 1 Torr. A velocity of the oxygen radical under these conditions is approximately 10 meters/second, thus giving the oxygen radical a range of about 10 cm before it reacts to form a more stable species. In light of this, to effectively treat a substrate with an oxygen plasma, the substrate should be disposed within this range (adjusted appropriately as a function of the pressure of the plasma or the velocity and/or lifetime of the radical species).

### Example Structure of Encapsulation Material

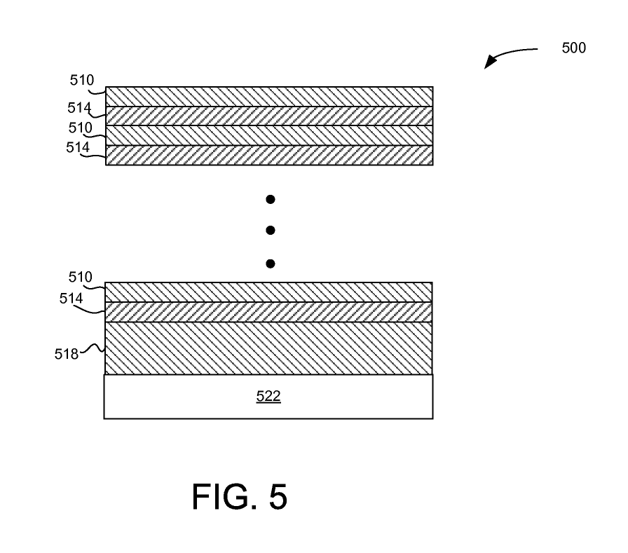

FIG. 5 is a cross sectional diagram of an encapsulation material 500, according to one embodiment. The encapsulation material 500 includes a substrate 522 and a bottom layer 518 on which other layers are deposited or formed. The substrate 522 may be flexible. The bottom layer 518 is deposited on the substrate 522. A first layer 514 (in this example, a hydrophobic layer) is formed on the bottom layer 518 by exposing the bottom layer 518 to precursor or converting part of the bottom layer 518.

In one embodiment, the bottom layer 518 is an aluminum oxide formed by ALD using trimethylaluminium (TMA) as source precursor and N₂O plasma as reactant precursor. The thickness of the bottom layer 518 is one angstrom to 500 angstroms. While not bound by theory, the reaction between TMA and the oxygen radicals generated from an N₂O plasma is thought to include the reaction shown in Equation 1:

2(CH₃)₃Al+O*→Al₂O₃+CH₄+CO₂+H₂O Equation 1

In this example, the injector 136A injects TMA via pipe 412A, and purge gas (e.g., Argon gas) via pipe 412B. Oxygen radicals (O*) may be generated from an N₂O plasma and injected by reactor 136D. In other examples, oxygen radicals can also be generated using O₂ plasma, O₃ plasma, (O₂+H₂) mixed plasma, and (O₃+H₂) mixed plasma. The injectors 136B and 136C are left unused during deposition of the aluminum oxide. The process of injecting TMA, purge gas and oxygen radicals may be repeated until a desired thickness of the bottom layer 518 is deposited on the substrate 522.

The first layer 514 may be formed by converting the aluminum oxide into a layer of Al—O—F compound, for example, by exposing the aluminum oxide (i.e., the bottom layer 518) to C₂F₆ plasma or (C₂F₆+H₂) plasma. This plasma generates fluorine radicals (F*) that are used to fluorinate the first layer 514. For this purpose, the reactor 136D may be provided with C₂F₆ gas or a mixture of C₂F₆ gas and H₂ gas. Radicals generated in the reactor 136D are injected onto the substrate 522.

Alternatively, the first layer 514 may be a layer of a polymer, such as plasma polymer, polyglycidylmethacrylate (PGMA), an epoxy-containing polymer layer, an Al—O—F compound, or Al—O—C—F polymer. In some examples, these compositions of the first layer 514 are deposited on the aluminum oxide using atomic layer deposition. In examples using PGMA, glycidylmethacrylate is used as reactant precursor by performing atomic layer deposition with N₂O remote-plasma. In examples using an Al—O—C—F polymer (or Al—O—F compound), TMA is used as the source precursor and nonafluorohexyltrimethooxysilane (C₉H₁₃F₉O₃) is used as reactant precursor. For this purpose, the injector 136A injects TMA via pipe 412A, and purge gas (e.g., Argon gas) via pipe 412B. The injector 136B injects nonafluorohexyltrimethooxysilane provided via pipe 416. The first layer 514 is oleophobic as well as hydrophobic. The thickness of the first layer 514 may be from 1 angstrom to 100 angstroms in some examples while the thickness may be from 2 angstroms to 10 angstroms in other examples to retain flexibility of the first layer 514 while preventing formation of defects in the first layer 514 during deposition.

A hydrophilic second layer 510 of an inorganic material, such as aluminum oxide (Al₂O₃) is deposited on the first layer 514. The second layer 510 includes no fluorine or a low concentration of fluorine, and may be formed by ALD using trimethylaluminium (TMA) as source precursor and N₂O plasma as reactant precursor. For this purpose, the injector 136A injects TMA via pipe 412A, and purge gas (e.g., Argon gas) via pipe 412B. Oxygen radicals may be generated and injected by reactor 136D. The reactors 136B and 136C remain unused during the deposition of the aluminum oxide.

The aluminum oxide layer is hydrophilic, and therefore, traps or confines any water molecules and hydroxyl radicals that penetrated into the second layer 510. Preferably, the aluminum oxide layer has a thickness of 1 to 5 angstroms which is approximately the size of one water molecule (or more specifically, one water molecule of a dimer). In order to prevent formation and growth of defects such as pin-holes that are larger than the size of the water molecule, the thickness of the aluminum oxide layer is not thicker than 5 angstroms. To prevent the migration of other gas molecules through the encapsulation layer, the aluminum oxide used to form the first layer 514 has a thickness of approximately between 1 angstrom to 8 angstroms. It is advantageous to minimize the thickness of the film, among other reasons, because the dimensions of defects, such as pin holes, increases as the film thickness increases, thereby providing a migration path for the water or gas molecule. The aluminum oxide layer may include low concentration of fluorine due to the presence of fluorine radicals remaining after the deposition of the first layer 514.

On the second layer 510, another first layer 514 of polymer or fluorinated material (e.g., Al—O—F compound or Al—O—C—F polymer) is formed. As shown in FIG. 5, the first layers 514 and the second layers 510 are stacked in an alternating manner on the bottom layer 518. The total number of first and second layers 514, 510 may be 5 to 10 layers, although more layers may be deposited on the bottom layer 518. By keeping each of the first and second layers 514, 510 below certain thicknesses, the flexibility of the encapsulation material 500 can be retained. After depositing the first and second layers 514, 510, another bottom layer 518 may be deposited followed by another set of alternating first and second layers 514, 510. The total thickness of the bottom layer 518, first layers 514 and the second layers 510 may be 10 to 500 angstroms. In one example, by depositing extremely thin aluminum oxide, or other hydrophilic inorganic material, as the first bottom layer 518 and the second layers 514, the stacks of these extremely thin layers with a polymer first layer 510 can permit bending of the substrate and/or products from 2 mm to 5 mm in bending radius. This bending radius is possible because, at extremely thin layers (i.e., 1 angstrom to 5 angstroms), aluminum oxide and other inorganic materials can be deformed without generating micro-cracks or dislocation as is typical in the deformation of bulk materials.

In another embodiment, the bottom layer 518 is an aluminum oxide formed on the substrate 522 by ALD using trimethylaluminium (TMA) as source precursor and N₂O plasma as reactant precursor. For this purpose, the injector 136A injects TMA via pipe 412A, and purge gas (e.g., Argon gas) via pipe 412B. N₂O radicals may be generated and injected by reactor 136D. The reactors 136A and 136B remain unused during the deposition of the aluminum oxide. The thickness of the bottom layer 518 is 10 to 50 angstroms. A layer of Al—Si—O—C—F polymer or Al—Si—O—F compound (where the Si can be replaced with another semiconductor or semi-metal element) is formed as a first layer 514 on the bottom layer 518 by exposing the bottom layer 518 to (C₂F₆+SiH₄) plasma. For this purpose, the injector 136A injects TMA via pipe 412A, and purge gas (e.g., Argon gas) via pipe 412B. A mixture of C₂F₆ gas and SiH₄ gas is provided to reactor 136D to generate radicals injected onto the bottom layer previous injected with TMA.

Alternatively, a layer of Al—Si—O—C—F polymer or Al—Si—O—F compound may be deposited on the bottom layer 518 as the first layer 514 by performing ALD using TMA as source precursor and Tridecafluoro-1,1,2,2-tetrahydrooctylmethylbis(dimethylamino)silane (FOMB(DMA)S, C₈F₁₃H₄(CH₃)Si(N(CH₃)₂)₂ as the reactant precursor. For this purpose, the injector 136A injects TMA via pipe 412A, and purge gas (e.g., Argon gas) via pipe 412B. The injector 136B injects Tridecafluoro-1,1,2,2-tetrahydrooctylmethylbis(dimethylamino)silane onto the bottom layer 518 previously injected with TMA. The thickness of the first layer 514 is 2 to 10 angstroms.

As in the previous embodiment, a layer of aluminum oxide is deposited as a second layer 510 on the first layer 514 by ALD using trimethylaluminium (TMA) as source precursor and N₂O plasma as reactant precursor. The aluminum oxide layer is hydrophilic. Preferably, the aluminum oxide layer has a thickness of 1 to 5 angstroms which is approximately the size of a water molecule. The second layer 510 traps water molecules and prevents the hydroxyl radicals and/or water molecules from penetrating the subsequent first layer.

On the second layer 510, another first layer 514 of Al—Si—O—C—F polymer or Al—Si—O—F compound is formed. The first layers 514 and the second layers 510 are stacked in an alternating manner on the bottom layer 518. The total number of first and second layers 514, 510 may be 5 to 10 layers, although more layers may be deposited on the bottom layer 518. After depositing the first and second layer 514, 510, another bottom layer 518 may be deposited followed by another set of alternating first and second layers 514, 510.

Instead of using (C₂F₆+SiH₄) plasma, (C₂F₆+TiCl₄) plasma including titanium may be used to deposit Al—Ti—O—C—F polymer as the first layer 514. Further, TiCl₄ or Tetradimethylamonotitanium (TDMAT) may be used as source precursor instead of TMA to form layers of TiO₂ as the bottom layer 522 or the second layer 510 and layers of Ti—O—C—F as the first layer 514. TiF₄ is formed on the TiO₂ layer by causing the reaction of TiCl₄ and F₂. TiOF₂ can be formed by causing the reaction of TiCl₄, O₂ and F₂. By combining and controlling thickness of TiO₂ layer, TiO₂F layer and TiF₄ layer, a reflection preventive layer may be obtained.

In still another embodiment, a molecular layer deposition (MLD) is performed to form a layer of Alucone (Al—O—(C—H)ₓ) as the bottom layer 518. Specifically, Alucone may be formed by injecting TMA, purging TMA molecules physisorbed on the substrate 522 by Argon gas, exposing the substrate 522 to Argon radical, injecting butanediol glycol or glycidol, performing purging by Argon gas, and repeating these processes until a desired thickness of Alucone is obtained. Alternatively, Alucone may be formed by injecting TMA, purging TMA molecules physisorbed on the substrate 522 by Argon gas, injecting butanediol glycol or glycidol, purging by Argon gas, exposing to Argon radicals, and repeating these processes until a desired thickness of Alucone is obtained. The thickness of Alucone layer used as the bottom layer 518 may be 10 to 500 angstroms.

The first layer 514 may be formed by converting the aluminum oxide into a layer of Al—O—F compound or Al—O—C—F polymer, for example, by exposing the aluminum oxide to C₂F₆ plasma or (C₂F₆+H₂) plasma. Alternatively, the first layer 514 may be a layer of Al—O—F compound or Al—O—C—F polymer deposited on the aluminum oxide by performing atomic layer deposition where TMA is used as source precursor and nonafluorohexyltrimethooxysilane (C₉H₁₃F₉O₃) is used as reactant precursor. The first layer 514 is oleophobic as well as hydrophobic. The thickness of the first layer 514 may be 2 to 10 angstroms in order to retain flexibility of the first layer 514 while preventing formation of defects in the first layer 514.

A second layer of 510 Alucone is deposited on the first layer 514 using the same processes for depositing the bottom Alucone layer 518. Preferably, the first layer 514 has a thickness of 1 to 5 angstroms which is approximately the size of a water molecule. Alucone is relatively hydrophilic compared to F-doped oxide, and hence, the first layer 514 traps water molecules and prevents the water molecules from penetrating to a subsequent first layer. In order to prevent formation and growth of defects such as pin-holes, the thickness of Alucone is less than 5 angstroms.

On the second layer 510, another first layer 514 of Al—O—F compound or Al—O—C—F polymer is formed. As shown in FIG. 5, the first layers 514 and the second layers 510 are stacked in an alternating manner on the bottom layer 518. The total number of first and second layers 510, 514 may be 5 to 10 layers, although more layers may be deposited on the bottom layer 518. After depositing the first and second layer 514, 510, another bottom layer 518 may be deposited followed by another set of alternating first and second layers 514, 510.

Although the first and second layers 514, 510 are described above as being distinct with identifiable boundaries for convenience, these layers may overlap or change gradually from one type of layer to another type of layer without distinct boundaries. The deposition process or conversion process may gradually increase or decrease the concentration of fluorine in the encapsulation material 500 as layers are deposited. As a result the concentration of fluorine in the encapsulation material 500 may fluctuate with increase in the depth of the encapsulation material 500. During the ALD, CVD or MLD process, compounds including fluorine may be gradually increased to form the first layers 514 or slowly decreased to form the second layers 510. The regions or layers of the encapsulation material 500 having a relatively high fluorine content corresponds to the first layers 514 whereas the regions or layers of the encapsulation material 500 having a relatively low fluorine content compared to the first layers 514 correspond to the second layers 510. The periodic layering of fluorine-containing layers or repeatedly stacked hydrophilic layers each having a thickness approximately the size of a water molecule forms multiple finite potential wells, thereby confining water molecules. The finite potential wells may also exhibit oleophobic behavior according to the alternating-layer structure.

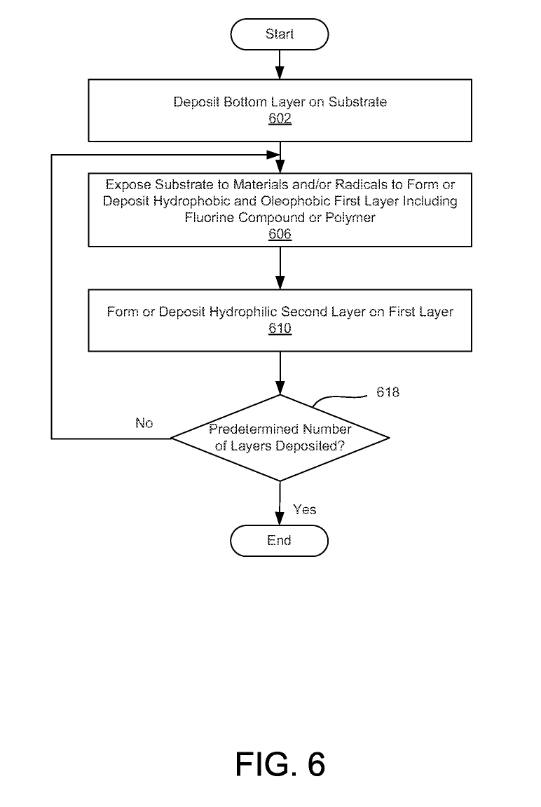

FIG. 6 is a flowchart illustrating the process of forming an encapsulation material, according to one embodiment. First, a bottom layer 518 is deposited 602 on a substrate 522 by ALD, CVD or MLD. The bottom layer 518 is, for example, aluminum oxide, Alucone or titanium oxide. The substrate 522 is exposed 606 to materials and/or radicals to form or deposit hydrophobic and oleophobic first layer 514. The first layer 514 is a material having hydrophobic properties, such as an organic compound containing metal atoms and/or inorganic species such as Al—O—C—H compound or Si—O—C—H compound or a fluoride containing compound or polymer to enhance hydrophobicity such as Al—O—F compound, Al—Si—O—C—F polymer, Al—Si—O—F compound, Al—O—C—F polymer, Al—O—C—F compound, Al—Ti—O—C—F compound and Ti—O—C—F compound.

Hydrophilic second layer 510 is formed or deposited 610 on the first layer 514. The second layer 510 may be aluminum oxide, silicon oxide, silicon nitride, zirconium oxide, titanium oxide, or their oxynitrides. It is then determined 618 if predetermined number of layers or thickness of materials are deposited or formed on the substrate 522. If the number of layers or thickness of materials is not reached, the process returns to exposing 606 the substrate 522 to materials or radicals to form or deposit the first layer. If the number of layers or thickness of materials is reached, then the process terminates.

In one embodiment, the process returns to depositing the bottom layer 518 after a predetermined number of first and second layers 514, 510 are deposited. That is, after it is determined 618 that a predetermined number of layers are deposited, the process may return to depositing 602 of the bottom layer and repeat the subsequent processes until an encapsulation material of desired configuration and thickness is obtained.

### Example Application of an Encapsulation Material

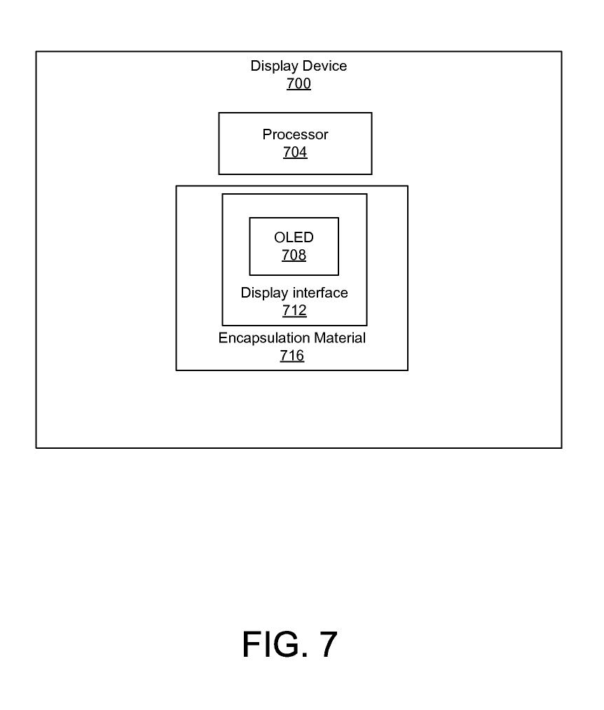

FIG. 7 illustrates one application of the encapsulation material described above, according to one embodiment. FIG. 7 depicts a schematic representation of a display device 700 that includes a processor 704, organic light emitting diode (“OLED”) device 708, a display interface 712, and an encapsulation material 716. The processor 704 generates and transmits signals to OLED 708 via display interface 712 for displaying images on the OLED 708. Encapsulation material 500 may be formed over the OLED 708 and the display interface 712 to prevent moisture or other contaminants from damaging the OLED 708 or the components of the display interface 712.

In another example, the encapsulation material 500 formed over a moisture sensitive flexible photovoltaic solar material (e.g., copper indium gallium di(selenide) or “CIGS”), or dye-sensitized solar cells (“DSSC”). In this application, the encapsulation material 500 prevents oxidization of electrically active materials in the solar material by the environment by blocking water (in the form of atmospheric moisture) or hydroxyl radicals from interacting with the electrically active materials.

Although the present invention has been described above with respect to several embodiments, various modifications can be made within the scope of the present invention. Accordingly, the disclosure of the present invention is intended to be illustrative, but not limiting.

1. A method for fabricating an encapsulation material, the method comprising:
providing a bottom layer of an inorganic material;
forming a hydrophobic first layer of an inorganic compound of at least one metal or at least one semi-metal, and oxygen, and fluorine, the hydrophobic first layer disposed on the bottom layer; and
forming a first alternating-layer stack by forming an inorganic hydrophilic second layer on the first layer, the second layer providing an energetic well for trapping water molecules and hydroxyl ions.

2. The method of claim 1, wherein providing the bottom layer comprises:
adsorbing a metal-organic precursor layer on a substrate using atomic layer deposition; and
exposing the metal-organic precursor layer to a radical species from a plasma, the plasma converting a surface portion of the metal-organic precursor layer to the inorganic compound of the first layer.

3. The method of claim 2, further comprising exposing the inorganic material of the bottom layer to a fluorine containing plasma to form an inorganic layer containing elements of the inorganic material and fluorine as the first layer.

4. The method of claim 2, further comprising exposing the inorganic material of the bottom layer to a fluorine and silane containing plasma to form an inorganic layer containing elements of the inorganic material, silicon, carbon, and fluorine as the first layer.

5. The method of claim 2, further comprising exposing the inorganic material of the bottom layer to a fluorine containing plasma with a titanium containing precursor to form an inorganic layer containing elements of the inorganic material, and titanium, carbon, and fluorine as the first layer.

6. The method of claim 1, wherein forming the hydrophobic first layer comprises depositing a polymer, a plasma polymer, or a polymer of aluminum, oxygen, carbon, and fluorine on the bottom layer.

7. The method of claim 1, wherein the hydrophobic first layer is from one angstrom to 100 angstroms thick.

8. The method of claim 1, wherein forming the hydrophobic first layer comprises:
exposing the bottom layer to tridecafluoro-1,1,2,2-tetrahydrooctylmethylbis(dimethylamino)silane; and
causing the deposited tridecafluoro-1,1,2,2-tetrahydrooctylmethylbis(dimethylamino)silane to react with trimethylaluminum in the bottom layer to form an Al—Si—O—C—F polymer as the first layer on the bottom layer.

9. The method of claim 1, wherein forming the inorganic hydrophilic second layer comprises:
exposing the first layer to a metal-organic precursor, molecules of which are adsorbed on the first layer; and
exposing the adsorbed metal-organic molecules to radicals of a plasma to convert the adsorbed metal-organic molecules to an inorganic layer.

10. The method of claim 1, further comprising forming at least one second alternating-layer stack on the first alternating-layer stack, the second alternating-layer stack including a second hydrophobic first layer and a second inorganic hydrophilic second layer.

11. The method of claim 1, wherein providing the bottom layer comprises:
exposing a substrate to a metal-organic precursor;
purging physisorbed metal-organic precursor from the substrate by injecting an inert gas onto the substrate;
exposing metal-organic molecules remaining on the substrate after the purging to radicals generated from a plasma; and
providing an organic precursor to the metal-organic molecules remaining on the substrate and exposed to the radicals.

12. The method of claim 1, wherein the inorganic hydrophilic second layer is from one angstrom to five angstroms thick.

13. An encapsulation material, comprising:
a bottom layer of an inorganic material;
a first alternating-layer stack, comprising:
a hydrophobic first layer; and
an inorganic hydrophilic second layer disposed on the first layer, the second layer providing an energetic well for trapping water molecules and hydroxyl ions.

14. The encapsulation material of claim 13, wherein the bottom layer is selected from the group consisting of Al₂O₃, ZrO₂, HfO₂, SiO₂, TiO₂, and combinations thereof.

15. The encapsulation material of claim 13, wherein the hydrophobic first layer is a polymer.

16. The encapsulation material of claim 13, wherein the second layer has a thickness equal to a molecular diameter of a water molecule.

17. The encapsulation material of claim 13, wherein the hydrophobic first layer is an organic aluminum-oxygen-carbon-fluorine compound.

18. The encapsulation material of claim 13, wherein the hydrophobic first layer is an inorganic aluminum-oxygen-fluorine compound.

19. The encapsulation material of claim 18, wherein the hydrophobic first layer is fabricated according to a process comprising:
exposing the bottom layer to a fluorine-containing plasma to convert a surface of the bottom layer to the inorganic aluminum-oxygen-fluorine compound of the hydrophobic first layer.

20. (canceled)

21. The encapsulation material of claim 13, wherein the first layer is formed by:
exposing a substrate to glycidylmethacrylate to deposit a layer of glycidylmethacrylate; and
exposing the deposited layer of glycidylmethacrylate to an N₂O plasma to convert the deposited layer to poly(glycidylmethacrylate).

22. The encapsulation material of claim 13 further comprising at least one second alternating-layer stack on the first alternating-layer stack.

23. A device comprising:
at least one active layer;
an encapsulation layer protecting the at least one active layer from contamination, the encapsulation layer comprising:
a bottom layer of an inorganic material;
a first alternating-layer stack, comprising:
a hydrophobic first layer disposed on the bottom layer; and
an inorganic hydrophilic second layer disposed on the hydrophobic first layer, the second layer providing an energetic well for trapping water molecules and hydroxyl ions.

24. The device of claim 23, further comprising a second alternating-layer stack disposed on the first alternating-layer stack, the second alternating-layer stack including a second hydrophobic first layer and a second inorganic hydrophilic second layer.
